(19) United States
(12) Patent Application Publication
(10) Pub. No.: US 2025/0079316 A1
(43) Pub. Date: Mar. 6, 2025

(54) SEMICONDUCTOR DEVICE AND ISOLATION STRUCTURE AND CONTACT ETCH STOP LAYER THEREOF

(71) Applicant: Taiwan Semiconductor Manufacturing Company, Ltd., Hsinchu (TW)

(72) Inventors: Szu-Hua CHEN, Hsinchu (TW); Jui-Chien HUANG, Hsinchu (TW); Wei-Yen WOON, Hsinchu (TW); Szuya LIAO, Hsinchu (TW)

(73) Assignee: Taiwan Semiconductor Manufacturing Company, Ltd., Hsinchu (TW)

(21) Appl. No.: 18/241,413

(22) Filed: Sep. 1, 2023

(51) Int. Cl. H01L 23/532; H01L 21/762; H01L 21/8234; H01L 27/088; H01L 29/40; H01L 29/51

(52) U.S. Cl. CPC H01L 23/53295; H01L 21/76224; H10D 64/118; H10D 64/693; H10D 84/0151; H10D 84/038; H10D 84/83; H10D 30/43; H10D 30/60; H10D 30/6757

(57) ABSTRACT

A semiconductor device and an isolation structure and a contact etch stop layer thereof are provided. According to an embodiment of the present disclosure, a semiconductor device is provided, which includes a first dielectric layer and a second dielectric layer. The first dielectric layer is deposited on the sidewall of an active device or formed in a trench of a gate structure. The second dielectric layer covers the first dielectric layer, wherein the dielectric constant of the first dielectric layer is between 2 and 2.5, and the dielectric constant of the second dielectric layer is less than or equal to 4. In some embodiments, a dielectric bilayer is composed of amorphous boron nitride and crystalline boron nitride.

### BACKGROUND

Currently, silicon nitride (SiN) is used as dielectric material due to its good electrical isolation property. However, SiN possesses high dielectric k value, which would degrade device performance as the pitch between the semiconductor devices is shrinking.

So far, dielectric materials are almost all Si-based, which cause limited etching selectivity. In addition, this technique of changing the size of the semiconductor also increases the complexity of the semiconductor manufacturing process. Therefore, in order to cope with the continuous improvement of semiconductor device technology, semiconductor manufacturing processes and related technologies also need to be improved. The existing Si-based dielectric materials are adequate for their intended purposes, but they are not entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic diagram of a semiconductor device according to an embodiment of the present disclosure.

FIG. 1B is a schematic diagram of amorphous boron nitride (a-BN) according to an embodiment of the present disclosure.

FIG. 1C is a schematic diagram of crystalline boron nitride according to an embodiment of the present disclosure.

FIG. 2 is a schematic diagram of a semiconductor device according to another embodiment of the present disclosure.

FIG. 3 is a schematic diagram of a semiconductor device according to another embodiment of the present disclosure.

FIG. 4 is a schematic diagram of a semiconductor device according to another embodiment of the present disclosure.

FIG. 5 is a schematic diagram of a semiconductor device according to another embodiment of the present disclosure.

FIG. 6 is a schematic diagram of a semiconductor device according to another embodiment of the present disclosure.

FIGS. 7A and 7B are respectively schematic diagrams of a semiconductor device according to another embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

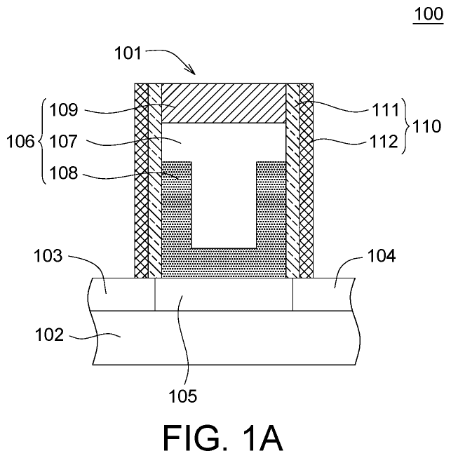

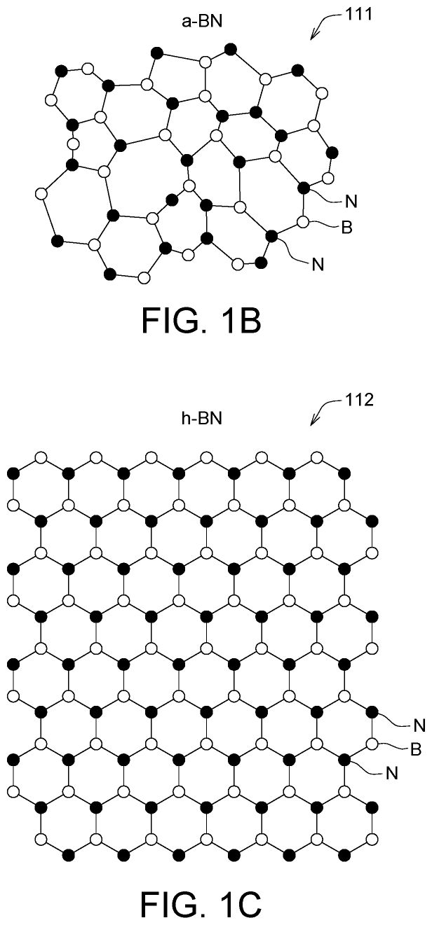

Referring to FIG. 1A, a schematic diagram of a semiconductor device 100 according to an embodiment of the present disclosure is shown. The semiconductor device 100 includes an active device 101, such as a transistor or other integrated circuits. The active device 101 includes a substrate 102 and a source region 103, a drain region 104 and a channel region 105 formed on the substrate 102. The channel region 105 is located between the source region 103 and the drain region 104. The substrate 102 is, for example, a silicon substrate. The substrate 102 may alternatively comprise other semiconductor materials in various embodiments, such as germanium, silicon carbide, gallium arsenide, gallium phosphide, indium phosphide, indium arsenide, indium antimonide, SiGe, GaAsP, AlInAs, AlGaAs, GaInAs, GaInP, GaInAsP or a combination thereof. The substrate 102 may include a doped semiconductor layer, such as a P-well and/or an N-well. In addition, the substrate 102 may be a semiconductor substrate on an insulating layer, such as a silicon-on-insulator (SOI) substrate.

The source region 103 and the drain region 104 may include N-type doped regions formed by doping a semiconductor material with an n-type dopant (e.g., phosphorus, arsenic, other n-type dopants, or combinations thereof) or a P-type doped region formed by doping a semiconductor material with a p-type dopant (e.g., boron, indium, other p-type dopants, or combinations thereof).

In addition, the active device 101 includes a gate structure 106 and a spacer layer 110 deposited along the sidewall of the gate structure 106, and the spacer layer 110 may be used as a sidewall spacer of the gate structure 106. The gate structure 106 includes a gate electrode layer 107 and a gate dielectric layer 108, and the gate electrode layer 107 overlaps with the gate dielectric layer 108. The gate structure 106 is formed between the source region 103 and the drain region 104 and is located above the channel region 105.

In some embodiments, the gate dielectric layer 108 may include an interface layer formed on the channel region 105 of fins and a high-K dielectric layer above the interface layer. The interface layer of the gate dielectric layer 108 may include a dielectric material, such as a silicon oxide layer (SiO₂) or a silicon oxynitride (SiON). The high-K dielectric layer of the gate dielectric layer 108 may include: HfO₂, TiO₂, HfZrO, Ta₂O₃, HfSiO₄, ZrO₂, ZrSiO₂, combinations thereof, or other suitable materials. In other embodiments, the gate dielectric layer 108 may include silicon dioxide or other suitable dielectrics. The gate dielectric layer 108 may be formed by chemical oxidation, thermal oxidation, atomic layer deposition (ALD), physical vapor deposition (PVD), chemical vapor deposition (chemical vapor deposition, CVD) and/or other suitable methods.

The gate electrode layer 107 may include a conductive layer, for example W, TiN, TaN, WN, Re, Ir, Ru, Mo, Al, Cu, Co, Ni, combinations thereof and/or other suitable compositions. In some embodiments, the gate electrode layer 107 may include a first set of metal materials for N-type FinFETs and a second set of metal materials for P-type FinFETs. Accordingly, FinFET device may include a dual work-function metal gate configuration. For example, the first metallic material (for an N-type device) may comprise a metal having a work function substantially aligned with that of the conduction band of the substrate, or an aligned metal having a work function substantially aligned with that of the conduction band of at least the channel region 105 of the fin. Likewise, for example, the second metallic material (for a P-type device) may include a metal having a work function substantially aligned with that of the conduction band of the substrate, or an aligned metal having a work function substantially aligned with that of the conduction band of at least the channel region 105 of the fin. Accordingly, the gate electrode layer 107 may provide a gate voltage for FinFET devices, including N-type and P-type FinFET devices. In some embodiments, the gate electrode layer 107 may alternately include polysilicon layers. The gate electrode layer 107 may be formed using physical vapor deposition (PVD), chemical vapor deposition (CVD), electron beam evaporation, and/or other suitable processes.

In addition, the gate structure 106 may also include a hard mask layer 109, and the hard mask layer 109 may include any material suitable for respectively patterning the gate electrode layer 107 with specific dimensions and/or attributes. The material of the hard mask layer 109 includes silicon nitride, silicon oxynitride, silicon carbon nitride or a combination thereof. The hard mask layer 109 may be deposited by CVD, PVD, ALD or other deposition techniques. In some embodiments, the gate structure 106 further includes a capping layer and/or other suitable layers.

In some embodiments, a spacer layer 110 serving as a sidewall spacer is formed on the sidewall of the gate structure 106. The spacer layer 110 may include a first dielectric layer 111 and a second dielectric layer 112. The second dielectric layer 112 covers the first dielectric layer 111. The dielectric constant of the first dielectric layer 111 is between 2 and 2.5, and the dielectric constant of the second dielectric layer 112 is greater than the first dielectric layer 111. The dielectric constant of the second dielectric layer 112 is less than or equal to 4, for example.

In some embodiments, the first dielectric layer 111 is, for example, amorphous boron nitride (see FIG. 1B), and the second dielectric layer 112 is, for example, crystalline boron nitride (see FIG. 1C). The crystalline boron nitride includes hexagonal boron nitride (h-BN) or boron nitride with other crystalline structures. In addition, the second dielectric layer 112 may also be a silicon-based material with a dielectric constant slightly higher than that of crystalline boron nitride, such as silicon oxide, silicon nitride, and silicon carbide, silicon oxynitride or a combination thereof.

In some embodiments, vapor deposition technology may be used to prepare amorphous boron nitride (a-BN) and crystalline boron nitride at low temperature and low pressure, which is easy to realize and manufacture, so as to replace the existing silicon-based dielectric materials. Amorphous boron nitride (a-BN) has an ultra-low dielectric constant (about 1.5-2.5), and has strong electrical and mechanical properties, and may be used as a dielectric isolation material to minimize electrical interference. In addition, amorphous boron nitride may be grown on wafer-scale substrates at low temperatures of 200-400° C. The lower k value of a-BN is due to the random distribution of nonpolar B—N ring structures in the amorphous boron nitride structure with less dipole arrangement. a-BN has a low leakage rate, but is easily oxidized by O₂ and H₂O. However, h-BN shows good oxidation resistance due to crystalline structure of BN, but the dielectric constant of h-BN is slightly higher than that of amorphous boron nitride.

Boron nitride (BN) is a III-V compound, a synthetic material with a carbon-like crystal structure. It is a wide bandgap semiconductor. Due to its unique physical and chemical properties, it has attracted great interest in science and advanced technology. It is one of the most promising superhard materials after diamond. BN forms four different crystal structures: hexagonal (h-BN), rhombohedral (r-BN), cubic (c-BN), and wurtzite (w-BN). The ground state structure of BN is the h-BN phase, which is a two-dimensional layered material with weak van der Waals forces. h-BN has various superior properties. Rhombohedral BN (r-BN) also forms a two-dimensional structure, similar to h-BN. Among other phases, r-BN is the least understood phase. Cubic boron nitride (c-BN) may be fabricated from h-BN and r-BN under high temperature and pressure conditions. Due to its extreme hardness, it is used as a protective coating for heavy tools. High-pressure and high-temperature treatment may achieve a phase transformation from h-BN to wurtzite structure (w-BN), which may be classified as a superhard material. Amorphous BN (a-BN) may be synthesized using various experimental techniques, such as high-frequency chemical vapor deposition and ball milling, but it is less explored and thus less understood relative to crystalline forms. Amorphous materials have coordination defects and strain topology, which may significantly affect their electrical and physical properties.

The a-BN film was grown via low-pressure chemical vapor deposition (LPCVD) at a low growth temperature of 200-400° C. and applied as a protection layer. Both structural and chemical states of the as-grown a-BN are verified by various spectroscopic and microscopic analyses.

In addition, crystalline boron nitride has a thermal expansion coefficient similar to GaAs and Si, high thermal conductivity and low dielectric constant (about 4), good insulation performance, good chemical stability, and may become an integrated circuit heat sink material and insulating coating. Crystalline boron nitride may be grown on a wafer-level substrate at a low temperature of 300-400° C., and its oxidation resistance is better than that of amorphous boron nitride, so it may protect amorphous boron nitride from oxygen attack. However, in another embodiment, in an oxygen-free environment or without the concern of being attacked by oxygen, the spacer layer 110 may be composed of a single dielectric layer of amorphous boron nitride, not limited to a dielectric bilayer of amorphous boron nitride and crystalline boron nitride.

Therefore, the bilayer BN consisting of a-BN and h-BN could improve both k value and anti-oxidation. Moreover, the use of the new dielectric material, BN, could increase the diversity for ordinary Si-based dielectric materials.

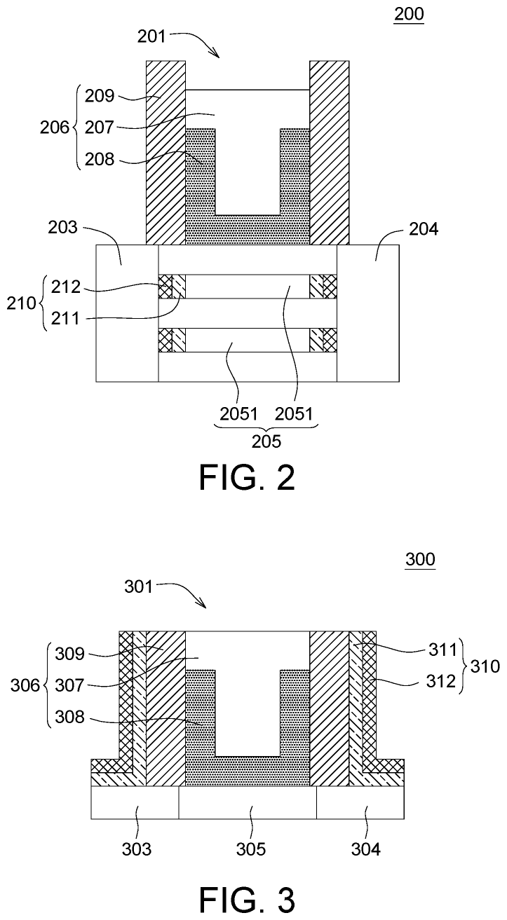

Referring to FIG. 2, a schematic diagram of a semiconductor device 200 according to another embodiment of the present disclosure is shown. The semiconductor device 200 includes an active device 201, and the active device 201 includes a source region 203, a drain region 204 and a channel region 205. The channel region 205 includes a plurality of semiconductor layers 2051 and a plurality of spacer layers 210, the semiconductor layers 2051 are stacked and arranged at intervals, and the spacer layers 210 are respectively formed on opposite side walls of the semiconductor layers 2051. The spacers layer 210 includes a first dielectric layer 211 and a second dielectric layer 212. The second dielectric layer 212 covers the first dielectric layer 211, wherein the dielectric constant of the first dielectric layer 211 is between 2 and 2.5, and the dielectric constant of the second dielectric layer 212 is greater than the first dielectric layer 211. The dielectric constant of the second dielectric layer 212 is less than or equal to 4, for example.

The spacer layer 210 is respectively formed between the source region 203 and the semiconductor layers 2051 and between the drain region 204 and the semiconductor layers 2051, in order to prevent electrical connection between the semiconductor layers 2051 and the corresponding source region 203 and the corresponding drain region 204, respectively.

In addition, the semiconductor device 200 further includes a gate structure 206. The gate structure 206 includes a gate electrode layer 207, a gate dielectric layer 208 and a spacer wall 209, the gate electrode layer 207 overlaps with the gate dielectric layer 208, and the spacer wall 209 surrounds along the sidewalls of the gate electrode layer 207 and the gate dielectric layer 208. The gate structure 206 is formed between the source region 203 and the drain region 204 and is located above the channel region 205. The structures, shapes and configurations of the gate dielectric layer 208 and the gate electrode layer 207 is similar to the gate structure 106, which has been described in the above embodiments, and will not be repeated here.

The present disclosure may be implemented in a semiconductor device 200 of nanosheet type. Accordingly, nanosheet-like devices (sometimes interchangeably referred to as gate-all-around (GAA) devices, multi-bridge-channel (MBC) devices, a surrounding gate transistor (SGT) or other similar name) includes a plurality of semiconductor layers 2051 stacked on top of another semiconductor layer 2051. The semiconductor layer 2051 of the nanosheet-like device may comprise any suitable shape and/or configuration. For example, the semiconductor layer 2051 may be one of many different shapes, such as a wire (or nanowire), a sheet (or nanosheet), a rod (or nanorod), and/or other suitable shapes. In other words, the term nanosheet-like device broadly includes devices having a semiconductor layer 2051 of nanowires, nanorods, and any other suitable shape. The semiconductor layer 2051 connects a pair of source/drain features such that charge carriers may flow from the source region 203 through the semiconductor layer 2051 to the drain region 204 during operation (e.g., when the transistor is turned on). In addition, the gate dielectric layer 208 is formed between the source/drain regions 203, 204 and the gate electrode layer 207, so that the source/drain regions 203, 204 may be isolated from the gate electrode layer 207. In the present disclosure, for example, CVD or ALD is used to deposit the inner spacer material on the sidewalls of the semiconductor layer 2051, and then form source/drain features on opposite sides of the channel region 205. In some embodiments, the source/drain regions 203, 204 may be formed by epitaxial processes, such as vapor-phase epitaxy (VPE), ultra-high vacuum CVD (UHV-CVD), molecular beam epitaxy (MBE) and/or other suitable processes. The source/drain features may be n-type or p-type and may be doped with n-type dopants such as phosphorus (P) or arsenic (As) or with p-type dopants such as boron (B) or Gallium (Ga).

In some embodiments, the spacer layer 210 as an inner spacer is formed under the gate structure 206, wherein the first dielectric layer 211 is, for example, amorphous boron nitride (a-BN), and the second dielectric layer 212 is, for example, crystalline boron nitride, e.g., hexagonal boron nitride or boron nitride with other crystalline structures. In addition, the second dielectric layer 212 may also be a silicon-based material with a dielectric constant slightly higher than that of crystalline boron nitride, such as silicon oxide, silicon nitride, and silicon carbide, silicon oxynitride or a combination thereof.

In some embodiments, vapor deposition technology may be used to prepare amorphous boron nitride and crystalline boron nitride at low temperature and low pressure, which is easy to realize and manufacture, so as to replace the existing silicon-based dielectric materials. Amorphous boron nitride has an ultra-low dielectric constant (about 1.5-2.5), and has strong electrical and mechanical properties, and may be used as a dielectric isolation material to minimize electrical interference. In addition, amorphous boron nitride may be grown on wafer-level substrates at low temperatures of 200-400° C., while crystalline boron nitride may be grown on wafer-level substrates at low temperatures of 300-400° C. The lower k value of a-BN is due to the random distribution of nonpolar B—N ring structures in the amorphous boron nitride structure with less dipole arrangement. a-BN has a low leakage rate, but is easily oxidized by O₂ and H₂O. In addition, the k value of h-BN is slightly higher than a-BN, but still much lower than the k value of commonly used SiN (k value is about 6) or SiCN (k value is about 7). Furthermore, h-BN shows good oxidation resistance due to crystalline structure of BN, so that crystalline boron nitride protects amorphous boron nitride from oxygen attack. However, in another embodiment, in an oxygen-free environment or without the concern of being attacked by oxygen, the spacer layer 210 may be composed of a single dielectric layer of amorphous boron nitride, not limited to a dielectric bilayer composed of amorphous boron nitride and crystalline boron nitride.

Referring to FIG. 3, a schematic diagram of a semiconductor device 300 according to another embodiment of the present disclosure is shown. The semiconductor device 300 includes an active device 301, and the active device 301 includes a source region 303, a drain region 304, a channel region 305 and a gate structure 306. The gate structure 306 includes a gate electrode layer 307, a gate dielectric layer 308 and a spacer wall 309. The structures, shapes and configurations of the source region 303, the drain region 304, the channel region 305 and the gate structure 306 are substantially the same as those of the gate structure 206, which is described in the above embodiments, and will not be repeated here. In addition, the semiconductor device 300 further includes a contact etch stop layer (CESL) 310, and the contact etch stop layer 310 surrounds the gate spacer 309 and is deposited along the upper surface of the source region 303 and the upper surface of the drain region 304.

In some embodiments, CESL may provide a mechanism for stopping the etch process. CESLs may be formed from dielectric materials that have a different etch selectivity than adjacent layers or components. The CESL may be deposited by deposition processes such as ALD, CVD or other deposition techniques. Additionally, a metal silicide layer may be formed on the top surfaces of the source/drain regions 303, 304 before forming source/drain contacts over the source regions 303 and/or drain regions 304, to reduce the contact resistance between the source/drain regions 303, 304 and the source/drain contacts. A pre-clean process may be used to prepare the top surfaces of the source/drain regions 303, 304 for metal suicide to remove remaining oxide and other contaminants. After the pre-clean process, a metal layer is formed over the source/drain regions 303, 304, and a wafer-targeted high temperature anneal is performed, which reacts the metal with silicon to form a metal silicide layer.

In some embodiments, the CESL 310 is deposited around the spacer wall 309 of the gate structure 306 and along the upper surface of the source region 303 and the upper surface of the drain region 304. The CESL 310 may include a first dielectric layer 311 and a second dielectric layer 312. The second dielectric layer 312 covers the first dielectric layer 311. The dielectric constant of the first dielectric layer 311 is between 2 and 2.5, and the dielectric constant of the second dielectric layer 312 is greater than the first dielectric layer 311. The dielectric constant of the second dielectric layer 312 is less than or equal to 4, for example. In some embodiments, the first dielectric layer 311 is, for example, amorphous boron nitride (a-BN), and the second dielectric layer 312 is, for example, crystalline boron nitride, e.g., hexagonal boron nitride (h-BN) or boron nitride with other crystalline structures. In addition, the second dielectric layer 312 may also be a silicon-based material with a dielectric constant slightly higher than that of crystalline boron nitride, such as silicon oxide, silicon nitride, and silicon carbide, silicon oxynitride or a combination thereof.

In some embodiments, vapor deposition technology may be used to prepare amorphous boron nitride and crystalline boron nitride at low temperature and low pressure, which is easy to realize and manufacture, so as to replace the existing silicon-based dielectric materials. Amorphous boron nitride has an ultra-low dielectric constant (about 1.5-2.5), and has strong electrical and mechanical properties, and may be used as a dielectric isolation material to minimize electrical interference. In addition, amorphous boron nitride may be grown on wafer-level substrates at low temperatures of 200-400° C., while crystalline boron nitride may be grown on wafer-level substrates at low temperatures of 300-400° C. The lower k value of a-BN is due to the random distribution of nonpolar B—N ring structures in the amorphous boron nitride structure with less dipole arrangement. a-BN has a low leakage rate, but is easily oxidized by O₂ and H₂O. In addition, the k value of h-BN is slightly higher than a-BN, but still much lower than the k value of commonly used SiN (k value is about 6) or SiCN (k value is about 7). Furthermore, h-BN shows good oxidation resistance due to crystalline structure of BN, so that crystalline boron nitride protects amorphous boron nitride from oxygen attack. However, in another embodiment, in an oxygen-free environment or without the concern of being attacked by oxygen, the CESL 310 may be composed of a single dielectric layer of amorphous boron nitride, not limited to a dielectric bilayer composed of amorphous boron nitride and crystalline boron nitride.

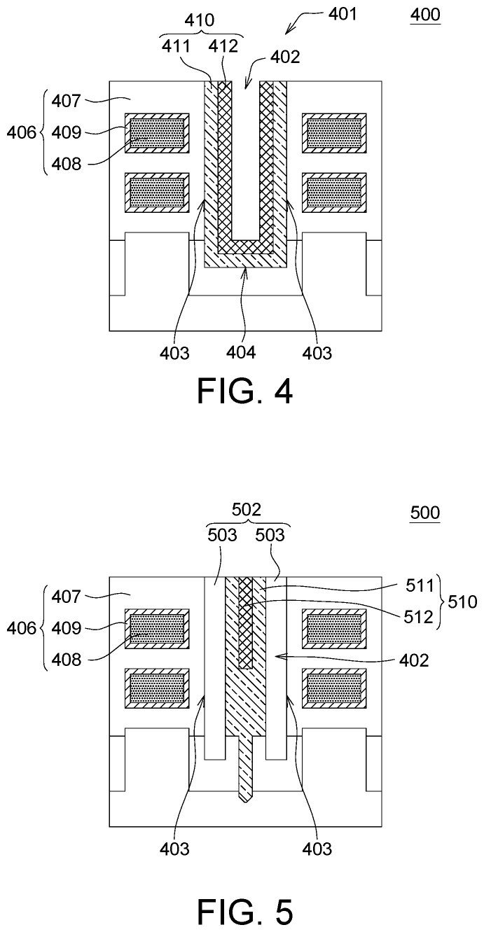

Referring to FIG. 4, a schematic diagram of a semiconductor device 400 according to another embodiment of the present disclosure is shown. The semiconductor device 400 includes an active device 401, and the active device 401 includes a gate structure 406. The gate structure 406 includes a gate electrode layer 407, a plurality of semiconductor layers 408 and a plurality of gate dielectric layers 409, the semiconductor layers 408 are deposited in the gate electrode layer 407, and the semiconductor layers 408 are stacked and arranged at intervals, and the gate dielectric layers 409 respectively surround the corresponding semiconductor layers 408 and electrically isolated between the gate electrode layers 407 and the semiconductor layers 409.

As shown in FIG. 4, the gate electrode layer 407 is formed on the gate dielectric layer 409 or surrounds the gate dielectric layer 409. The gate electrode layer 407 may include a single layer or a multilayer structure, and the gate electrode layer 407 may include titanium nitride (TiN), titanium aluminum (TiAl), titanium aluminum nitride (TiAlN), tantalum nitride (TaN), tantalum Aluminum (TaAl), tantalum aluminum nitride (TaAlN), tantalum aluminum carbide (TaAlC), tantalum nitride carbon (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals or other suitable metal materials or combinations thereof. In addition, the gate dielectric layer 409 may include an interface layer (not shown) and a high-k gate dielectric layer. The interface layer is located on the semiconductor layer 408 or surrounds the semiconductor layer 408, and the high-k value gate dielectric layer is located on the interface layer and surrounds the interface layer. In some embodiments, the interfacial layer includes silicon oxide. The gate dielectric layer 409 may include a high-k dielectric material, such as hafnium oxide. Alternatively, the gate dielectric layer 409 may also include other high-k dielectric materials, such as titanium oxide (TiO₂), hafnium zirconium oxide (HfZrO), tantalum oxide (Ta₂O₅), hafnium silicon oxide (HfSiO₄), zirconium oxide (ZrO₂), zirconia silicon oxide (ZrSiO₂), lanthanum oxide (La₂O₃), aluminum oxide (Al₂O₃), zirconia (ZrO), yttrium oxide (Y₂O₃), SrTiO₃ (STO), BaTiO₃ (BTO), BaZrO, lanthanum hafnium oxide (HfLaO), lanthanum silicon oxide (LaSiO), aluminum silicon oxide (AlSiO), hafnium tantalum oxide (HfTaO), hafnium titanium oxide (HfTiO), (Ba,Sr)TiO₃(BST), silicon nitride (SiN), silicon oxynitride (SiON), combinations thereof, or other suitable materials. The gate dielectric layer 108 may be formed by any suitable method, such as CVD, ALD, PVD, other suitable techniques or combinations thereof. In this process stage, the gate dielectric layer 409 may surround three or four sides of the semiconductor layer 408, and the thickness of the gate dielectric layer 409 may be about 1.5 nm to 3 nm.

In some embodiments, the gate structure 406 includes a trench 402 exposing opposite sidewalls 403 and a bottom surface 404 of the gate electrode layer 407. In addition, the semiconductor device 100 includes a liner 410 deposited along opposite sidewalls 403 of the gate electrode layer 407 and covering the bottom surface 404. The liner 410 may be used as an isolation structure for a cut metal gate (CMG). The cut metal gate process refers to the process used to form the isolation structure, which may divide the continuous gate across multiple active regions into multiple segments. Such isolation structures may be referred to as gate cutting features, gate blocking features, or cut metal gate (CMG) features.

Subsequently, an isolation material is filled into the trench 402 between adjacent portions of the gate structure 406. The trench 402 are referred to as a cut metal gate trench (CMG trench) in this disclosure. As devices continue to be scaled down, the aspect ratio (defined as the ratio of the height of the CMG trench to the width of the CMG trench) of the CMG trench 402 generally increases. In the present disclosure, the CMG trench 402 is filled with one or more dielectric materials to form the liner 410. The liner 410 includes a first dielectric layer 411 and a second dielectric layer 412, and the second dielectric layer 412 covers the first dielectric layer 411. The dielectric constant of the first dielectric layer 411 is between 2 and 2.5, and the dielectric constant of the second dielectric layer 412 is greater than that of the first dielectric layer 411. The dielectric constant of the second dielectric layer 412 is less than or equal to 4, for example.

In some embodiments, the liner 410 acts as an isolation structure or a layer of the isolation structure inside the CMG trench 402. The first dielectric layer 411 is, for example, amorphous boron nitride (a-BN), and the second dielectric layer 412 is, for example, crystalline boron nitride, e.g., hexagonal boron nitride (h-BN) or boron nitride with other crystalline structures. In addition, the second dielectric layer 412 may also be a silicon-based material with a dielectric constant slightly higher than that of crystalline boron nitride, such as silicon oxide, silicon nitride, silicon carbide, silicon oxynitride or a combination thereof.

In some embodiments, amorphous boron nitride and crystalline boron nitride may be prepared at low temperature and low pressure using vapor deposition technology, which is easy to implement and manufacture the liner 410 to replace the existing silicon-based dielectric material. Amorphous boron nitride has an ultra-low dielectric constant (about 1.5-2.5), and has strong electrical and mechanical properties, and may be used as a dielectric isolation material to minimize electrical interference. In addition, amorphous boron nitride may be grown on wafer-level substrates at low temperatures of 200-400° C., while crystalline boron nitride may be grown on wafer-level substrates at low temperatures of 300-400° C. The lower k value of a-BN is due to the random distribution of nonpolar B—N ring structures in the amorphous boron nitride structure with less dipole arrangement. a-BN has a low leakage rate, but is easily oxidized by O₂ and H₂O. In addition, the k value of h-BN is slightly higher than a-BN, but still much lower than the k value of commonly used SiN (k value is about 6) or SiCN (k value is about 7). Furthermore, h-BN shows good oxidation resistance due to crystalline structure of BN, so that crystalline boron nitride protects amorphous boron nitride from oxygen attack. However, in another embodiment, under an oxygen-free environment or without the concern of being attacked by oxygen, the liner 410 may be composed of a single dielectric layer of amorphous boron nitride, not limited to a dielectric bilayer composed of amorphous boron nitride and crystalline boron nitride and crystalline boron nitride.

Referring to FIG. 5, a schematic diagram of a semiconductor device 500 according to another embodiment of the present disclosure is shown. The semiconductor device 500 includes a gate structure 406 and an isolation structure 502. The gate structure 406 includes a gate electrode layer 407, a plurality of semiconductor layers 408 and a plurality of gate dielectric layers 409, and the semiconductor layers 408 and gate dielectric layers 409 are arranged similar to that of FIG. 4, which is not repeated here. Since the opposing sidewalls 403 of the gate electrode layer 407 contain a metallic material, at least the exterior of the isolation structure 502 (which is in direct contact with the opposing sidewalls 403) includes cut metal gate (CMG) feature 503, which does not, for example, contain active chemical components, such as oxygen, or, in another embodiment, at least the interior of the isolation structure 502 includes a filler 510, for example, free of active chemical components such as oxygen, or, in yet another embodiment, both of the interior and the exterior of the isolation structure 502 do not contain active chemical components, such as oxygen.

In some embodiments, the CMG feature 503 of the isolation structure 502 are surround the filler 510. The filler 510 includes a first dielectric layer 511 and a second dielectric layer 512. The second dielectric layer 512 covers the first dielectric layer 511. The dielectric constant of the first dielectric layer 511 is between 2 and 2.5, and the dielectric constant of the second dielectric layer 512 is greater than the first dielectric layer 511. In some embodiments, the first dielectric layer 511 is, for example, amorphous boron nitride (a-BN), and the second dielectric layer 512 is, for example, crystalline boron nitride, e.g., hexagonal boron nitride (h-BN) or boron nitride with other crystalline structures.

In some embodiments, amorphous boron nitride and crystalline boron nitride may be prepared at low temperature and low pressure by vapor deposition technology, which is easy to implement and manufacture the filler 510 to replace the existing silicon-based dielectric material. Amorphous boron nitride has an ultra-low dielectric constant (about 1.5-2.5), and has strong electrical and mechanical properties, and may be used as a dielectric isolation material to minimize electrical interference. In addition, amorphous boron nitride may be grown on wafer-level substrates at low temperatures of 200-400° C., while crystalline boron nitride may be grown on wafer-level substrates at low temperatures of 300-400° C. The lower k value of a-BN is due to the random distribution of nonpolar B—N ring structures in the amorphous boron nitride structure with less dipole arrangement. a-BN has a low leakage rate, but is easily oxidized by O₂ and H₂O. In addition, the k value of h-BN is slightly higher than a-BN, but still much lower than the k value of commonly used SiN (K value is about 6) or SiCN (K value is about 7). Furthermore, h-BN shows good oxidation resistance due to crystalline structure of BN, so that crystalline boron nitride protects amorphous boron nitride from oxygen attack. However, in another embodiment, under an oxygen-free environment or without the concern of being attacked by oxygen, the filler 510 may be composed of a single dielectric layer of amorphous boron nitride, not limited to a dielectric bilayer composed of amorphous boron nitride and crystalline boron nitride.

Optionally, the isolation structure 502 may be deposited using CVD, PVD, ALD, or other suitable methods. In this embodiment, the isolation structure 502 is deposited using ALD to ensure that the filler 510 completely fills the CMG trench 402. In some embodiments, the isolation structure 502 may be a cut-on-poly-oxide-definition-edge (CPODE) spacer. In addition, the CMG trench 402 may be formed with a predetermined aspect ratio using an anisotropic etch, which may include a dry etch process or a suitable etch process. For example, the dry etching process may use oxygen-containing gas, hydrogen gas, fluorine-containing gas (for example, CF₄, SF₆, CH₂F₂, CHF₃ and/or C₂F₆), chlorine-containing gas (for example, Cl₂, CHCl₃, CCl₄ and/or BCl₃), Bromine-containing gas (e.g., HBr and/or CHBr₃), iodine-containing gas, other suitable gases and/or plasma and/or combinations thereof.

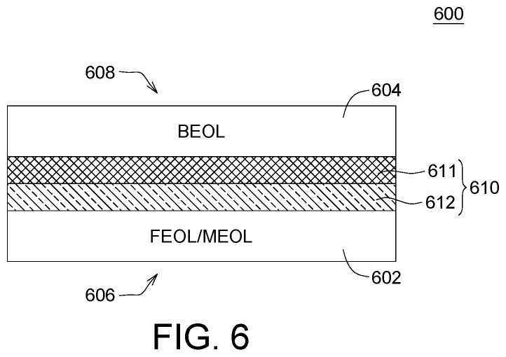

Referring to FIG. 6, a schematic diagram of a semiconductor device 600 according to another embodiment of the present disclosure is shown. The semiconductor device 600 includes at least one interlayer dielectric layer 602, 604 (ILD) and a contact etch stop layer 610. The contact etch stop layer 610 is formed on the ILD layer 602. The contact etch stop layer 610 includes a first dielectric layer 611 and a second dielectric layer 612. The second dielectric layer 612 covers the first dielectric layer 611. The dielectric constant of the first dielectric layer 611 is between 2 and 2.5, and the dielectric constant of the second dielectric layer 612 is greater than the first dielectric layer 611. The contact etch stop layer 610 may serve as an interface layer between the front end/middle end (FEOL/MEOL) features 606 and the back end (BEOL) features 608. FEOL/MEOL refers to a front end of line or a middle end of line, and BEOL refers to a back end of line, the BEOL is second major stage of the semiconductor manufacturing process where the interconnects are formed within the devices manufactured in the FEOL/MEOL.

In some embodiments, after the CESL 610 is deposited, another ILD layer 604 may be formed on the CESL 604. The IDL layers 602 and 604 may be made of amorphous SiOx, SiOxCyHz, SiOxCy, SiCx or related low-k value materials, and the range of k value may be between 2.0 and 3.0 or between 2.5 and 3.5. The interlayer dielectric layers 602 and 604 may be made of SiOx, SiOxCyHz, SiOxCy, SiCx or related low-k materials with ordered pores or non-porosity. As used herein, the term “ordered pores” refers to voids or air gaps formed in a dielectric material in a predetermined arrangement and filled with air. The interlayer dielectric layers 602 and 604 with ordered pores have the characteristics of low dielectric constant and high mechanical strength. In some embodiments, the interlayer dielectric layers 602, 604 may be deposited at a temperature between 450 degrees Celsius and 300 degrees Celsius by chemical vapor deposition (CVD), physical vapor deposition (PVD), atomic layer deposition (ALD), spin coating or other suitable process formation. In some embodiments, the fabrication of the interlayer dielectric layers 602 and 604 may be performed with an additional annealing or ultraviolet (ultraviolet, UV) curing process, but may not be used.

In some embodiments, the first dielectric layer 611 is, for example, amorphous boron nitride (a-BN), and the second dielectric layer 612 is, for example, crystalline boron nitride, e.g., hexagonal boron nitride (h-BN) or boron nitride of other crystalline structures. In addition, the second dielectric layer 612 may also be a silicon-based material with a dielectric constant slightly higher than that of crystalline boron nitride, such as silicon oxide, silicon nitride, and silicon carbide. carbide), silicon oxynitride or a combination thereof.

In some embodiments, vapor deposition technology may be used to prepare amorphous boron nitride and crystalline boron nitride at low temperature and low pressure, which is easy to realize and manufacture the contact etch stop layer 610 to replace the existing silicon-based dielectric material. Amorphous boron nitride has an ultra-low dielectric constant (about 1.5-2.5), and has strong electrical and mechanical properties, and may be used as a dielectric isolation material to minimize electrical interference. In addition, amorphous boron nitride may be grown on wafer-level substrates at low temperatures of 200-400° C., while crystalline boron nitride may be grown on wafer-level substrates at low temperatures of 300-400° C. The lower k value of a-BN is due to the random distribution of nonpolar B—N ring structures in the amorphous boron nitride structure with less dipole arrangement. a-BN has a low leakage rate, but is easily oxidized by O₂ and H₂O. In addition, the k value of h-BN is slightly higher than a-BN, but still much lower than the k value of commonly used SiN (k value is about 6) or SiCN (k value is about 7). Furthermore, h-BN shows good oxidation resistance due to crystalline structure of BN, so that crystalline boron nitride protects amorphous boron nitride from oxygen attack. However, in another embodiment, in an oxygen-free environment or without the concern of being attacked by oxygen, the contact etch stop layer 610 may be composed of a single dielectric layer of amorphous boron nitride, not limited to a dielectric bilayer composed of amorphous boron nitride and crystalline boron nitride.

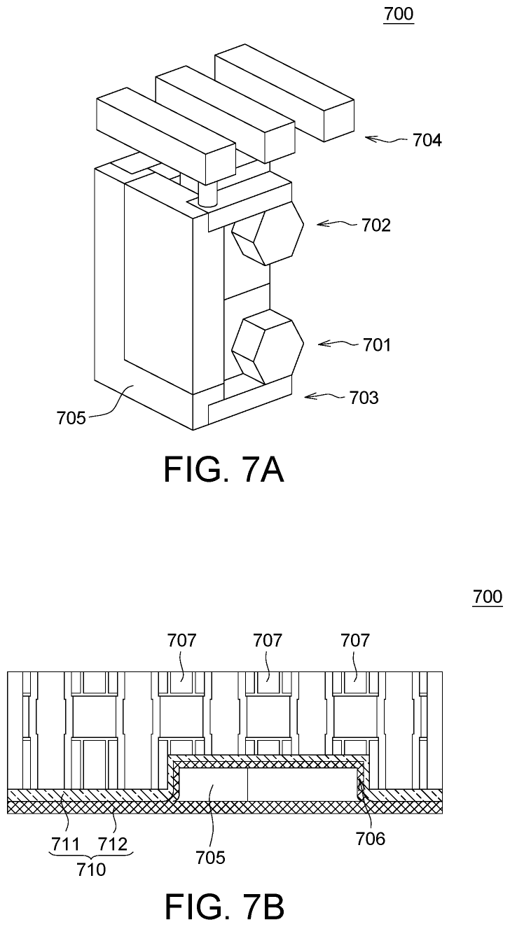

Referring to FIGS. 7A and 7B, schematic diagrams of a semiconductor device 700 according to another embodiment of the present disclosure are respectively shown. The semiconductor device 700 includes at least one lower epitaxy 701, at least one upper epitaxy 702, at least one lower metal layer 703, at least one upper metal layer 704, and a CMG trench 706. The lower epitaxy 701 is formed on a lower port ion of the semiconductor device 700, and the upper epitaxy 702 is formed on an upper portion of the semiconductor device 700 and separated from the lower epitaxy 701. The lower epitaxy 701 is one set of source and drain, and the upper epitaxy 702 is another set of source and drain. The lower epitaxy 701 and the upper epitaxy 702 may define, for example, a NMOS and a PMOS, respectively.

In some embodiments, the VLI liner 710 is formed in the vertical direction of the CMG trench 706 to separate the cut metal gates 707 from a VLI conductive layer 705. The VLI conductive layer 705 is connected between the upper metal layer 704 and the lower metal layer 703. The VLI liner 710 includes a first dielectric layer 711 and a second dielectric layer 712. The second dielectric layer 712 covers the first dielectric layer 711. The dielectric constant of the first dielectric layer 711 is between 2 and 2.5, and the dielectric constant of the second dielectric layer 712 is greater than the first dielectric layer 711. The VLI liner 710 may be used as an isolation layer.

In some embodiments, the first dielectric layer 711 is, for example, amorphous boron nitride (a-BN), and the second dielectric layer 712 is, for example, crystalline boron nitride, e.g., hexagonal boron nitride (h-BN) or boron nitride of other crystalline structures. In addition, the second dielectric layer 712 may also be a silicon-based material with a dielectric constant slightly higher than that of crystalline boron nitride, such as silicon oxide, silicon nitride, silicon carbide, silicon oxynitride or a combination thereof.

In some embodiments, vapor deposition technology may be used to prepare amorphous boron nitride and crystalline boron nitride at low temperature and low pressure, and it is easy to implement and manufacture the VLI liner 710 to replace the existing silicon-based dielectric material. Amorphous boron nitride has an ultra-low dielectric constant (about 1.5-2.5), and has strong electrical and mechanical properties, and may be used as a dielectric isolation material to minimize electrical interference. In addition, amorphous boron nitride may be grown on wafer-level substrates at low temperatures of 200-400° C., while crystalline boron nitride may be grown on wafer-level substrates at low temperatures of 300-400° C. The lower k value of a-BN is due to the random distribution of nonpolar B—N ring structures in the amorphous boron nitride structure with less dipole arrangement. a-BN has a low leakage rate, but is easily oxidized by O₂ and H₂O. In addition, the k value of h-BN is slightly higher than a-BN, but still much lower than the k value of commonly used SiN (k value is about 6) or SiCN (k value is about 7). Furthermore, h-BN shows good oxidation resistance due to crystalline structure of BN, so that crystalline boron nitride protects amorphous boron nitride from oxygen attack. However, in another embodiment, in an oxygen-free environment or without the concern of being attacked by oxygen, the VLI liner 710 may be composed of a single dielectric layer of amorphous boron nitride, not limited to a dielectric bilayer composed of amorphous boron nitride and crystalline boron nitride.

The present disclosure relates to a semiconductor device and an isolation structure and a contact etch stop layer thereof, wherein amorphous boron nitride and crystalline boron nitride may be prepared at low temperature and low pressure by vapor deposition technology, which is easy to realize and manufacture, and may replace the existing silicon-based dielectric materials. Amorphous boron nitride has an ultra-low dielectric constant (about 1.5-2.5), and has strong electrical and mechanical properties, and may be used as a dielectric isolation material to minimize electrical interference. Furthermore, h-BN shows good oxidation resistance due to crystalline structure of BN, so that crystalline boron nitride protects amorphous boron nitride from oxygen attack.

According to an embodiment of the present disclosure, a semiconductor device including a first dielectric layer and a second dielectric layer is provided. The first dielectric layer is deposited on the sidewall of an active device. The second dielectric layer covers the first dielectric layer, wherein the dielectric constant of the first dielectric layer is between 2 and 2.5, and the dielectric constant of the second dielectric layer is less than or equal to 4.

According to an embodiment of the present disclosure, an isolation structure including a first dielectric layer and a second dielectric layer is provided. The first dielectric layer is formed in a trench of a gate structure. The second dielectric layer covers the first dielectric layer, wherein the dielectric constant of the first dielectric layer is between 2 and 2.5, and the dielectric constant of the second dielectric layer is less than or equal to 4.

According to an embodiment of the present disclosure, a contact etch stop layer is provided, including a first dielectric layer and a second dielectric layer. The second dielectric layer covers the first dielectric layer, wherein the dielectric constant of the first dielectric layer is between 2 and 2.5, and the dielectric constant of the second dielectric layer is less than or equal to 4, wherein at least one of the first dielectric layer and the second dielectric layer is a non-silicon-based material.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first dielectric layer deposited on a sidewall of an active device; and
a second dielectric layer covering the first dielectric layer, wherein a dielectric constant of the first dielectric layer is between 2 and 2.5, and a dielectric constant of the second dielectric layer is less than or equal to 4.

2. The semiconductor device according to claim 1, wherein at least one of the first dielectric layer and the second dielectric layer is a non-silicon-based material.

3. The semiconductor device according to claim 1, wherein the first dielectric layer comprises amorphous boron nitride, and the second dielectric layer comprises crystalline boron nitride.

4. The semiconductor device according to claim 3, wherein the first dielectric layer is formed by depositing at a temperature of 200-400° C., and the second dielectric layer is formed by depositing at a temperature of 300-400° C.

5. The semiconductor device according to claim 1, wherein the active device comprises a gate structure and a spacer layer arranged along sidewalls of the gate structure, the spacer layer comprises the first dielectric layer and the second dielectric layer.

6. The semiconductor device according to claim 1, wherein the active element includes a substrate and a source region, a drain region, and a channel region formed on the substrate, and the channel region is located between the source region and the drain region.

7. The semiconductor device according to claim 6, wherein the channel region includes a plurality of semiconductor layers and a plurality of spacer layers, the semiconductor layers are stacked and arranged at intervals, and the spacer layers are respectively formed on opposite sidewalls of the semiconductor layers, wherein each of the spacer layers comprises the first dielectric layer and the second dielectric layer.

8. The semiconductor device according to claim 1, wherein the active device comprises a source region, a drain region, a channel region, a gate structure and a gate spacer, and the channel region is located between the source region and the drain region, the gate structure is formed on the channel region, and the gate spacer is arranged around sidewalls of the gate structure.

9. The semiconductor device according to claim 8, wherein the semiconductor device comprises a contact etch stop layer deposited on the sidewalls of the gate spacer and along the upper surface of the source region and the upper surface of the drain region, and the contact etch stop layer comprises the first dielectric layer and the second dielectric layer.

10. The semiconductor device according to claim 1, wherein the active device comprises a gate structure, the gate structure comprises a gate electrode layer, a plurality of semiconductor layers and a plurality of gate dielectric layers, and the semiconductor layers deposited in the gate electrode layer, and the semiconductor layers are stacked and arranged at intervals, the gate dielectric layers surround the semiconductor layers respectively and are electrically isolated from the gate electrode layer and the semiconductor layers, wherein the gate structure comprises a trench exposing opposite sidewalls and a bottom surface of the gate electrode layer.

11. The semiconductor device according to claim 10, wherein the semiconductor device comprises a liner, the liner is arranged on the opposite sidewalls of the gate electrode layer and covers the bottom surface, the liner comprises the first dielectric layer and the second dielectric layer.

12. The semiconductor device according to claim 11, wherein the liner serves as an isolation structure for a cut metal gate (CMG) or is located in an isolation structure of a cut-on-poly-oxide-definition-edge (CPODE).

13. An isolation structure, comprising:
a first dielectric layer formed in a trench of a gate structure; and
a second dielectric layer covering the first dielectric layer, wherein a dielectric constant of the first dielectric layer is between 2 and 2.5, and a dielectric constant of the second dielectric layer is less than or equal to 4.

14. The isolation structure according to claim 13, wherein at least one of the first dielectric layer and the second dielectric layer is a non-silicon-based material.

15. The isolation structure according to claim 13, wherein the first dielectric layer comprises amorphous boron nitride and the second dielectric layer comprises crystalline boron nitride.

16. The isolation structure according to claim 13, wherein the gate structure comprises a gate electrode layer, the trench exposes opposite sidewalls and a bottom surface of the gate electrode layer, and the first dielectric layer and the second dielectric layer serve as a liner for a cut metal gate (CMG).

17. The isolation structure according to claim 13, wherein the first dielectric layer and the second dielectric layer serve as a filler for a cut-on-poly-oxide-definition-edge (CPODE) of the gate structure.

18. A contact etch stop layer, comprising:
a first dielectric layer; and
a second dielectric layer covering the first dielectric layer, wherein a dielectric constant of the first dielectric layer is between 2 and 2.5, and a dielectric constant of the second dielectric layer is less than or equal to 4, wherein at least one of the first dielectric layer and the second dielectric layer is a non-silicon-based material.

19. The contact etch stop layer according to claim 18, wherein the contact etch stop layer acts as an interface layer between a front-end-of-line feature or a middle-end-of-line feature and a back-end-of-line feature.

20. The contact etch stop layer according to claim 18, wherein the first dielectric layer comprises amorphous boron nitride and the second dielectric layer comprises crystalline boron nitride.
